(19) United States
(12) Patent Application Publication
(10) Pub. No.: US 2024/0320405 A1
(43) Pub. Date: Sep. 26, 2024

(54) WORKFLOW FOR OBJECTIVELY CLASSIFYING HYDROCARBON SHOWS

(71) Applicant: SAUDI ARABIAN OIL COMPANY, Dhahran (SA)

(72) Inventors: Ibrahim Atwah, Dhahran (SA); Nikolaos A. Michael, Dhahran (SA)

(73) Assignee: SAUDI ARABIAN OIL COMPANY, Dhahran (SA)

(21) Appl. No.: 18/187,424

(22) Filed: Mar. 21, 2023

(51) Int. Cl. G06F 30/28

(52) U.S. Cl. CPC G06F 30/28

(57) ABSTRACT

A method includes providing of input data relating to one or more hydrocarbon shows, and the input data include descriptors characterizing one or more wells at two or more different depths. The method further includes transforming the input data into numerical data for a first database via a first protocol. The numerical data include numerical indices characterizing the one or more wells at the two or more different depths. A related system includes a sample collector that collects one or more rock samples from a wellbore, each of the one or more rock samples corresponding to one or more hydrocarbon shows. The system also includes an arrangement for analyzing the rock samples. A computer processor, operatively connected to the sample collector and arrangement, includes functionality for carrying out the method steps.

### BACKGROUND

Hydrocarbon shows are direct and indirect observations of the hydrocarbons present in core and cutting samples collected during and after well drilling. Though other methods may typically be used to detect the presence of commercial quantities of hydrocarbons, hydrocarbon show observations can detect hydrocarbons at trace levels.

Such information can be obtained both during and after well drilling, and can assist significantly in optimizing drilling operations and geological interpretations. It can also inform changes in planned targets, and may even help pinpoint hydrocarbon-bearing reservoir rocks that may otherwise be overlooked. However, it is often a very cumbersome process to gather and display all related data, usually reverting to unstructured verbal descriptions that are conceptually disconnected and fail to provide an adequately clear, legible general overview.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In one aspect, embodiments disclosed herein relate to a method wherein input data relating to one or more hydrocarbon shows are provided using a computer processor, and the input data include descriptors characterizing one or more wells at two or more different depths. The method further includes transforming, using the computer processor, the input data into numerical data for a first database via a first protocol. The numerical data include numerical indices characterizing the one or more wells at the two or more different depths.

In one aspect, embodiments disclosed herein relate to a system for objectively classifying hydrocarbon shows. The system includes a sample collector that collects one or more rock samples from a wellbore, each of the one or more rock samples corresponding to one or more hydrocarbon shows. The system also includes an arrangement for analyzing the rock samples. A computer processor is operatively connected to the sample collector and arrangement and includes functionality for: providing input data relating to the one or more hydrocarbon shows, wherein the input data correspond to analyzed rock samples; wherein the input data include descriptors characterizing one or more wells at two or more different depths; and transforming the input data into numerical data for a first database via a first protocol; wherein the numerical data include numerical indices characterizing the one or more wells at the two or more different depths.

In one aspect, embodiments disclosed herein relate to a non-transitory computer readable medium storing instructions executable by a computer processor. The instructions include functionality for: providing input data relating to one or more hydrocarbon shows; wherein the input data include descriptors characterizing one or more wells at two or more different depths; transforming the input data into numerical data for a first database via a first protocol; wherein the numerical data include numerical indices characterizing the one or more wells at the two or more different depths.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 schematically illustrates, in a cross-sectional elevational view, a well site with a drilling rig and wellbore in accordance with one or more embodiments.

FIG. 2 depicts a general workflow for transforming hydrocarbon shows to numerical indices characterizing individual wells and for mapping related data, in accordance with one or more embodiments.

FIG. 3 provides an illustrative example of raw data collected from hydrocarbon show observations, in accordance with one or more embodiments.

FIG. 4 illustrates a conventional text-based classification system that may be utilized in accordance with one or more embodiments.

FIG. 5 provides an illustrative example of an indexing scheme for objectively grading hydrocarbon shows, in accordance with one or more embodiments.

FIG. 6 depicts a transformation of data from a larger database of hydrocarbon show indices to a summarized database, in accordance with one or more embodiments.

FIG. 7 illustrates a working example of maps that derived on the basis of summarized index data, in accordance with one or more embodiments.

FIG. 8 shows a flowchart of a method in accordance with one or more embodiments.

FIG. 9 schematically illustrates a computing device and related components, in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

Generally, as addressed herein in accordance with one or more embodiments, three manifestations of hydrocarbon show types are observed for both gas and oil fluid phases. These manifestations include continuous-phase oil/gas, residual oil/gas, and in-kerogen oil/dissolved gas. The description of hydrocarbon shows can encompass multiple examinations of the rock sample and the extracted fluids. Moreover, conventional hydrocarbon show detection methods, that can help provide valuable input data as contemplated herein, will describe the examined sample odor, staining and bleeding, acid reaction, fluorescence, and solvent extracts.

In accordance with one or more embodiments, there is broadly contemplated herein an arrangement for the automatic classification, categorization, and analysis of hydrocarbon shows observed from rock core samples or drilling cuttings, wherein descriptive text information is converted to a numerical index. In this manner, unstructured and scattered data can be transformed to derive attributes that may be utilized during drilling operations and mapped and analyzed for geological modeling and interpretation.

In accordance with one or more embodiments, text format data describing hydrocarbon shows is converted to an index which leads to a derived attribute named the “hydrocarbon show index”. The hydrocarbon show index may be established on a scale from 0 to 1. Further, the index may characterize the conclusiveness of evidence at hand, and may also characterize a degree of hydrocarbon mobility (especially if hydrocarbons are present in significant, commercially viable quantities).

In accordance with one or more embodiments, a hydrocarbon show index attribute is grouped either by the geological formation or by well location, ultimately creating a summarized attribute. That summarized attribute can then be mapped and analyzed. After mapping, the gradients of change in the hydrocarbon show index can be calculated and converted to hydrocarbon show migration pathways. The hydrocarbon migration pathways based on hydrocarbon shows can be used to validate basin modeling results and to derisk (i.e., ascertain acceptable risk for) prospect opportunities for hydrocarbon exploration.

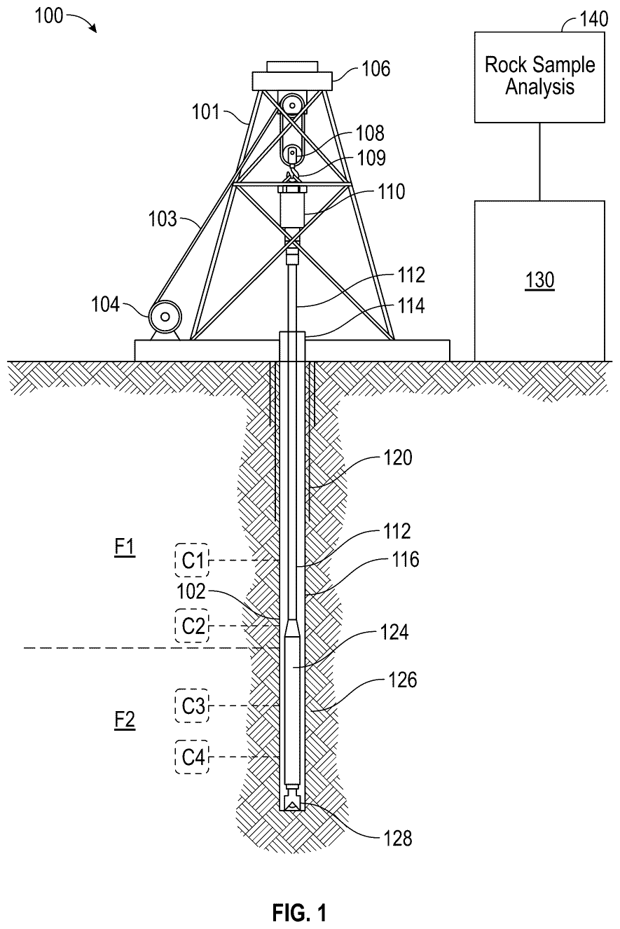

Turning now to the figures, to facilitate easier reference when describing FIGS. 1-9, reference numerals may be advanced by a multiple of 100 in indicating a similar or analogous component or element among FIGS. 1-9.

FIG. 1 schematically illustrates, in a cross-sectional elevational view, a well site with a drilling rig and wellbore in accordance with one or more embodiments. As such, FIG. 1 illustrates a non-restrictive example of a well site 100. The well site 100 is depicted as being on land. In other examples, the well site 100 may be offshore, and drilling may be carried out with or without use of a marine riser. A drilling operation at well site 100 may include drilling a wellbore 102 into a subsurface including various formations 126. More than one wellbore 102 may be included at the well site 100, but for the present purposes of illustration only one wellbore 102 is shown. For the purpose of drilling a new section of wellbore 102, a drill string 112 is suspended within the wellbore 102. The drill string 112 may include one or more drill pipes connected to form conduit and a bottom hole assembly (BHA) 124 disposed at the distal end of the conduit. The BHA 124 may include a drill bit 128 to cut into the subsurface rock. The BHA 124 may include measurement tools, such as a measurement-while-drilling (MWD) tool or a logging-while-drilling (LWD) tool (not shown), as well as other drilling tools that are not specifically shown but would be understood to a person skilled in the art.

Additionally, the drill string 112 may be suspended in wellbore 102 by a derrick structure 101. A crown block 106 may be mounted at the top of the derrick structure 101. A traveling block 108 may hang down from the crown block 106 by means of a cable or drill line 103. One end of the drill line 103 may be connected to a drawworks 104, which is a reeling device that can be used to adjust the length of the drill line 103 so that the traveling block 108 may move up or down the derrick structure 101. The traveling block 108 may include a hook 109 on which a top drive 110 is supported. The top drive 110 is coupled to the top of the drill string 112 and is operable to rotate the drill string 112. Alternatively, the drill string 112 may be rotated by means of a rotary table (not shown) on the surface 114. Drilling fluid (commonly called mud) may be pumped from a mud system 130 into the drill string 112. The mud may flow into the drill string 112 through appropriate flow paths in the top drive 110 or through a rotary swivel, if a rotary table is used (not shown).

Further, by way of general background in accordance with one or more embodiments, and during a drilling operation at the well site 100, the drill string 112 is rotated relative to the wellbore 102 and weight is applied to the drill bit 128 to enable the drill bit 128 to break rock as the drill string 112 is rotated. In some cases, the drill bit 128 may be rotated independently with a drilling motor. Generally, it is also possible to rotate the drill bit 128 using a combination of a drilling motor and the top drive 110 (or a rotary swivel if a rotary table is used instead of a top drive) to rotate the drill string 112. While cutting rock with the drill bit 128, drilling fluid or “mud” (not shown) is pumped into the drill string 112. The mud flows down the drill string 112 and exits into the bottom of the wellbore 102 through nozzles in the drill bit 128. The mud in the wellbore 102 then flows back up to the surface 114 in an annular space between the drill string 112 and the wellbore 102 carrying entrained cuttings to the surface 114. The mud with the cuttings is returned to the mud system 130 to be circulated back again into the drill string 112. Typically, the cuttings are removed from the mud, and the mud is reconditioned as necessary, before pumping the mud again into the drill string 112.

Continuing with FIG. 1, drilling operations are completed upon the retrieval of the drill string 112, the BHA 124, and the drill bit 128 from the wellbore 102. In some embodiments of wellbore 102 construction, production casing operations may commence. A casing string 116, which is made up of one or more larger diameter tubulars that have a larger inner diameter than the drill string 112 but a smaller outer diameter than the wellbore 102, is lowered into the wellbore 102 on the drill string 112. Generally, the casing string 116 is designed to isolate the internal diameter of the wellbore 102 from the adjacent formation 126. Once the casing string 116 is in position, it is set and cement is typically pumped down through the internal space of the casing string 116, out of the bottom of the casing shoe 120, and into the annular space between the wellbore 102 and the outer diameter of the casing string 116. This secures the casing string 116 in place and creates the desired isolation between the wellbore 102 and the formation 126. At this point, drilling of the next section of the wellbore 102 may commence.

In accordance with one or more embodiments, FIG. 1 also illustrates a general example of rock formations and sample collection sites. As shown, the wellbore 102 traverses two different rock formations F1 and F2, each with distinct physical and geological characteristics. As will be better understood herebelow, rock samples may be collected at several locations (or depths) in wellbore 102 by way of identifying and objectively classifying hydrocarbon shows. Thus, in the present rudimentary example, rock samples may be collected at locations C1 and C2 within rock formation F1 and at locations C3 and C4 within rock formation F2.

Generally, in accordance with one or more embodiments, rock samples at C1-C4 may be collected via any suitable method. For instance, a sample collector may be embodied by the drill bit 128 as it cuts into the formations F1 and F2, wherein rock cuttings at each of the locations C1-C4 may return to the surface with circulated mud and to the mud system 130. The collected rock samples may then be separated for further processing and for analysis via a suitable arrangement or venue 140 for rock sample analysis. Such an arrangement 140 may include an on-site or remote laboratory, merely by way of illustrative example. As an alternative, in a separate downhole run subsequent to drilling, a sample collector may be embodied by a BHA 124 that includes a smaller drill or other cutting implement for retrieving a sample from any or all of the locations C1-C4.

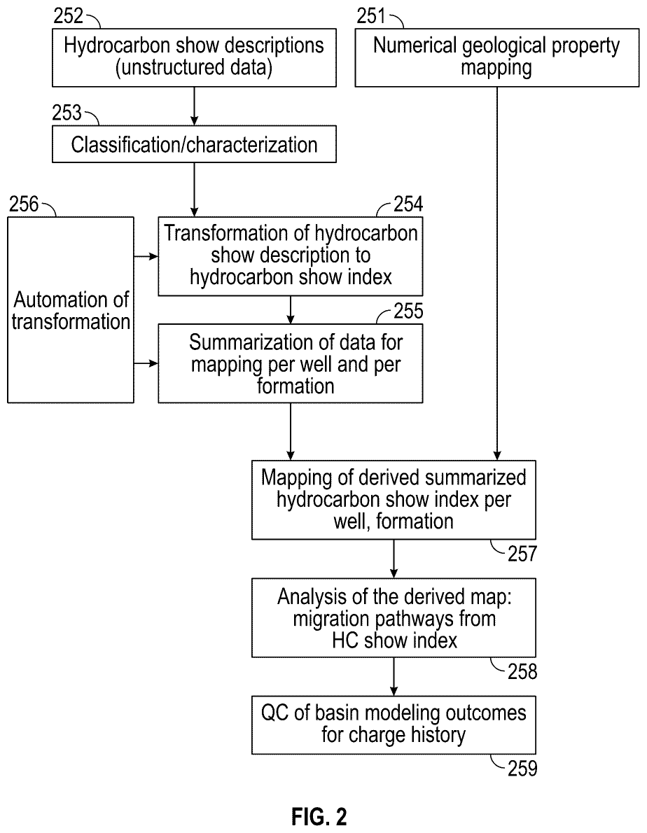

The disclosure now turns to working examples of a workflow for objectively classifying hydrocarbon shows in accordance with one or more embodiments, as described and illustrated with respect to FIGS. 2-9. It should be understood and appreciated that these merely represent illustrative examples, and that a great variety of possible implementations are conceivable within the scope of embodiments as broadly contemplated herein.

As shown in FIG. 2, in accordance with one or more embodiments, initial input data are received, including one or more geological property maps with numerical data (251) and hydrocarbon show descriptions (252). The hydrocarbon shows may then be classified or characterized utilizing any of a great variety of known regimes (253). These input data may then be transformed in a manner to be appreciated below.

In accordance with one or more embodiments, the descriptions (252) may be in the form of one or more relatively large databases containing show observations in an unstructured format. This initial, unstructured data may be transformed or structured via a classification regime (253) that involves applying text-based descriptions to the data. The one or more maps (251) essentially can be used at a later stage (as described further herein) as a medium for appending and viewing numerical indices as discussed herein.

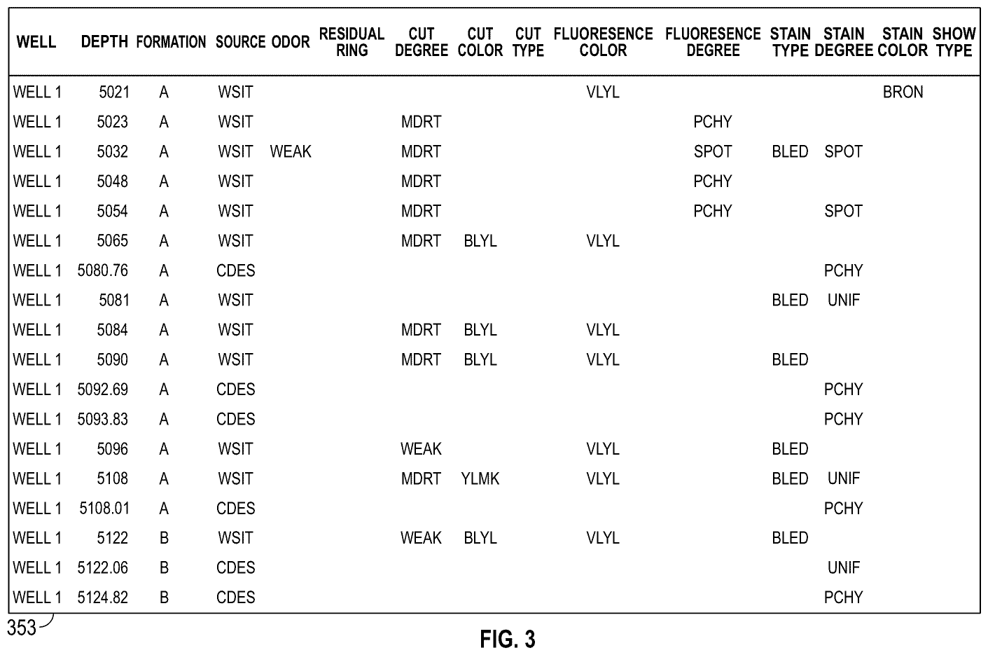

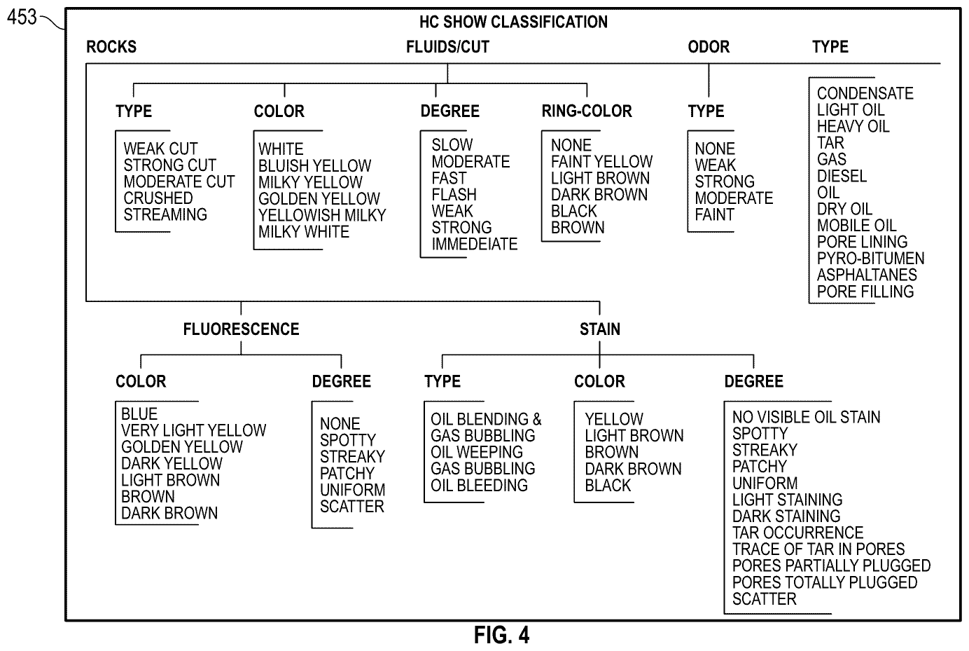

FIG. 3 provides an illustrative example of data 353 collected from hydrocarbon show observations, in accordance with one or more embodiments and that is structured to include text-based descriptions as noted. Additionally, FIG. 4 illustrates a text-based classification system 453 that may be utilized to help initially structure the data in the manner shown in FIG. 3. Accordingly, this corresponds to the classification/characterization step 253 shown in FIG. 2, and joint reference may continue to be made to both FIGS. 3 and 4. It should also be understood that the rows and columns of data 353 shown in FIG. 3 can be manually input by a user, or can be the result of initial/unstructured data being automatically transformed to result in the rows and columns of FIG. 3; either could be guided by or based on the classification system 453 of FIG. 4. Also, it should be understood that the classification system 453 shown in FIG. 4 is merely provided by way of illustrative and non-restrictive example. The working example shown is generally subjective in nature but also reflective of standards and nomenclature widely known to those of ordinary skill in the art. A wide variety of possible classification systems or schemes are thus conceivable within the scope of embodiments broadly discussed and contemplated herein.

In accordance with one or more embodiments, the illustrative example of data shown in FIG. 3 are for a given well (Well 1) at different depths, with respect to geological formations A and B. Thus, this may be regarded as input data relating to different hydrocarbon shows, and in principle may be obtained with respect to one or more shows. By way of illustrative example, such data may derive from rock samples collected in a wellbore (see FIG. 1, 102) and analyzed at a suitable venue (see FIG. 1, 140). The “Source” column indicates the source of data; thus here the sources WSIT (Well Site) and CDES (Core Description) are shown as examples. Other columns, if applicable to the depth in question, contain additional data. The examples of columns shown here are: Odor, Residual Ring, Cut Degree, Cut Color, Cut Type, Fluorescence Color, Fluorescence Degree, Stain Type, Stain Degree, Stain Color and Show Type. The examples of data provided throughout these columns include: MDRT (Moderate); WEAK (Weak); BLYL (Bluish Yellow); YMLK (Yellowish Milky); VLYL (Very Light Yellow); PCHY (Patchy); SPOT (Spotty); BLED (Bleeding); UNIF (Uniform); and BRON (Brown). These data may be regarded as descriptors characterizing Well 1 at different depths, and in principle may characterize one or more wells at two or more different depths.

As noted, and in accordance with one or more embodiments, the data in FIG. 3 have at least been initially structured via the text-based classification system 453 shown in FIG. 4, merely by way of illustrative and non-restrictive example. As shown in FIG. 4, hydrocarbon show classifications may generally be subdivided into four major categories, including rocks, fluids/cut, odor, and type. The rocks and fluids categories are further divided into subcategories. Thus, the “rocks” category may be divided into “fluorescence” and “stain”. “Fluorescence” may be characterized via a range of possible colors (e.g., blue to bright yellow to dark brown) and possible “intensities” or degrees (e.g., “none”, “spotty”, “streaky”). In this connection, the fluorescence degree can reflect the general structure of the fluorescing zone of the rock relative to the non-fluorescent area, which varies from none to spotty to uniform to scattered fluorescence.

In accordance with one or more embodiments, “stain” may be characterized via type, color and degree as shown. Thus, rock stain color, by way of example, may range from yellow to light brown to black. The intensity or degree of stain describes the morphology of the stain, and its occurrence relative to the rock matrix, which can vary from not visible to uniform, to scattered staining. Additionally stain type may indicate a condition such as “oil weeping”, “gas bubbling”, “oil bleeding” or “oil bleeding and gas bubbling” as shown.

In accordance with one or more embodiments, as shown in FIG. 4, the “fluids/cut” category can include characterizations of type, color, degree (or fluorescence intensity) and ring color. More particularly, in the fluids/cut category, all the described hydrocarbon show information is related to the extracted fluids from the rock, generally referred to as the cut. In this connection, examined samples can typically be dried out, with an organic solvent (i.e., acetone, chloroethene, petroleum ether) then applied thereto, and the resulting fluid residue can then be examined and described under normal white and ultraviolet light.

In this connection, in accordance with one or more embodiments, the ring color reflects the observed color of the cut under white light; such observations can range from none to light yellow to black. The cut degree refers to flow intensity and viscosity or the extracted fluids from the examined rock sample, which can range from slow to fast and strong. The cut color is a description of the fluorescence color of the solvent extract. Such extract fluorescence can vary from white to bluish yellow to milky white. The cut type is the intensity and an observed amount of extracts which can vary from weak to moderate to streaming.

Further the “odor” category can include characterizations of as shown, relating to a smell detected subjectively. Finally, the general “type” category can include characterizations of the actual hydrocarbon such as condensate, light oil, heavy oil, etc., as shown.

In accordance with one or more embodiments, the classified/characterized raw data 353 then provides a basis for automatic transformation to numerical indices. Particularly, in a manner now to be described, hydrocarbon show descriptions deriving from classification/characterization (see FIG. 2, 253) are then converted to numerical values (see FIG. 2, 254) that can ultimately be appended onto the maps that have been input into the process (see FIG. 2, 251). In principle, this may be regarded as transforming input data into numerical data for a first database via a first protocol, to be further appreciated herebelow by way of illustrative example; alternatively, the first database may also be termed or regarded as a “raw database”.

In accordance with one or more embodiments, the concept of a numerical index (or hydrocarbon show index) can be based on two factors, the first of which is the conclusiveness of observed evidence for the presence of hydrocarbons. For the second factor, hydrocarbon shows can be objectively graded on a basis of fluid movability, reflecting a degree to which the shows may be producible if they happen to be present in commercial quantities in the subsurface. “Objective grading” can be understood as assigning a numerical grade or index to one or more aspects of a hydrocarbon show, in a manner to be better understood and exemplified herebelow.

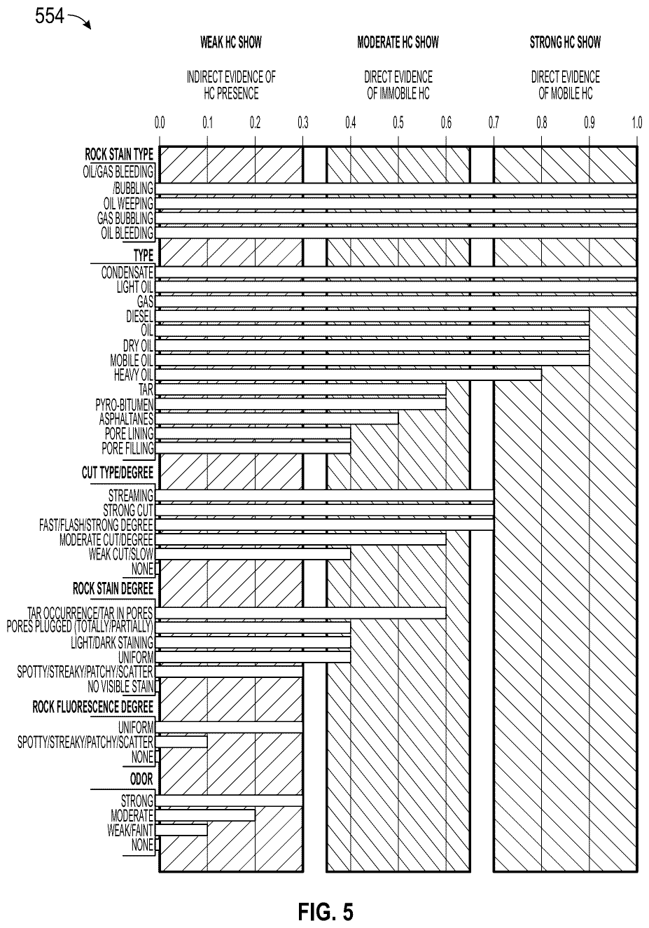

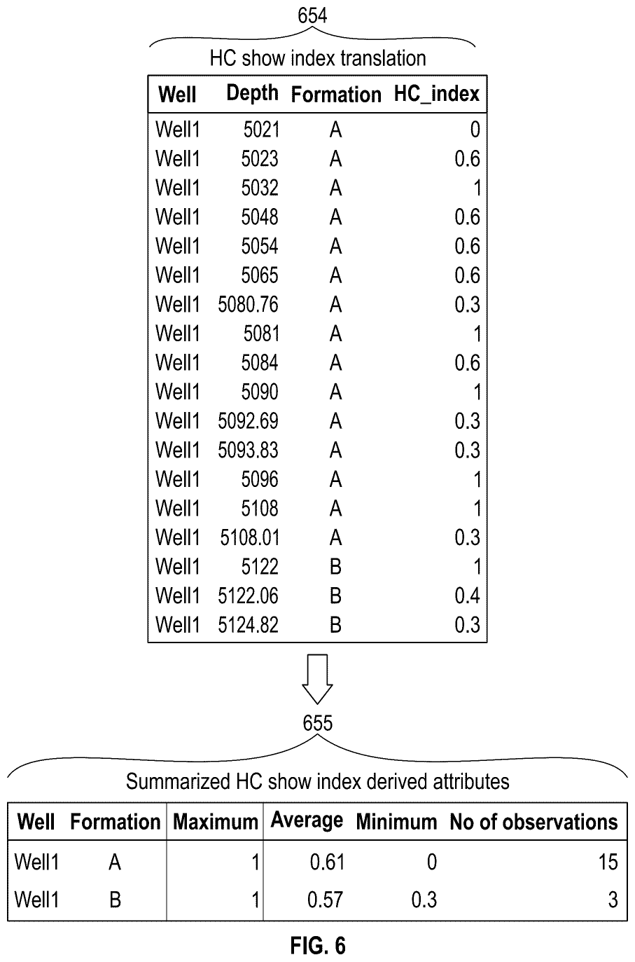

Accordingly, in accordance with one or more embodiments, an illustrative example of an indexing scheme 554 for objectively grading or characterizing hydrocarbon shows is shown in FIG. 5. As shown in FIG. 5, index values ranging from 0 to 1 are divided into three main categories: strong hydrocarbon show, moderate hydrocarbon show, and weak hydrocarbon show. Though presented merely by way of illustrative example, FIG. 5 also shows index values that may be associated with certain rock stain types, general hydrocarbon show types, cut types/degrees, rock stain degrees, rock fluorescence degrees and odors. Thus toward the aforementioned objective grading, for a particular well & depth, several characteristics taken from the chart in FIG. 5 can be considered, and then collapsed into a single index number; this is exemplified with respect to different depths for a single well as shown in FIG. 6 at 654. Collapsing into the single number may be undertaken in any of a variety of ways, such as via taking the maximum of the numbers derived from one or more characteristics (such as stain type, stain degree, odor, etc.). Alternatively, the numbers derived from the one or more characteristics may be averaged, or a suitable weighted average may even be employed.

The “strong” category represents direct evidence of producible hydrocarbons, such as the presence of condensate or the occurrence of gas bubbling; the category ranges in value from 0.7 to 1 and such values are assigned based on fluid mobility. Therefore, light and mobile hydrocarbons will exhibit higher index values (closer to 1) compared to shows with heavy crude oil fluids (closer to 0.7).

In accordance with one or more embodiments, the “moderate” hydrocarbon show category represents direct evidence of the presence of hydrocarbons that cannot be produced such as asphaltenes, tar mat, and pyrobitumen. The moderate category can range and in value from 0.4 to 0.6, with higher values representing a higher likelihood of the presence of producible hydrocarbons.

In accordance with one or more embodiments, the “weak hydrocarbon show” category represents indirect evidence for the presence of hydrocarbons but is inconclusive, such as the presence of weak odor or scattered rock fluorescence. This category ranges in value from 0 to 0.3, in which higher values represent a higher intensity in the indirect evidence for the presence of hydrocarbons while 0 represents a lack of direct and indirect evidence of a hydrocarbon show. Generally, in this category, there is still a possibility of some direct evidence for the presence of hydrocarbons at or near the upper bound of 0.3. However, the evidence would be in such insufficient quantity that it likely could not be observed directly by the five human senses.

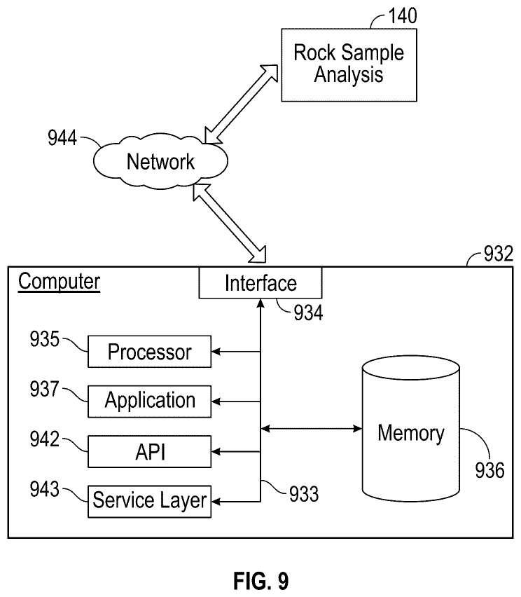

Returning to FIG. 2, and in accordance with one more embodiments, the generation of numerical indices as noted can be applied to each observation in a whole database (254), such as the classified/characterized raw data 353 (see FIG. 3). This then can serve as a first step, via the aforementioned first protocol, toward creating legible output data (e.g., on a map). As another transformative step, and via a second protocol, an entire well can be characterized by a single index, wherein one or more (n) observations collapse into a single representative derived or summarized number, resulting in a smaller, “summarized” database (255). Automated transformation processes (256) may thus be utilized for each of these steps or protocols, e.g., utilizing a computer 932 such as that described and illustrated with respect to FIG. 9, via processor(s) 935 and displayed or output via interface 934.

Thus, in accordance with one or more embodiments, to apply numerical indices to each observation in a whole database (254), via the aforementioned first protocol a transformation process (256) may retrieve classified/characterized raw data (see FIG. 3, 353), categorize the data and via text recognition assign an index for each observation (e.g., via the scheme 554 shown in FIG. 5). Via the aforementioned second protocol, a transformation process (256) may then take the numerical index data determined and rendered per observation (254) and transform the same into the single indices per well or formation as noted (255). Transformation processes (256) as noted may be run periodically to ensure that an evergreen and current database is continually provided.

In accordance with one or more embodiments, there are different possibilities for obtaining the summarized database 255, via a transformation process 256. By way of an illustrative and non-restrictive example, individual numerical indices may be summarized per interval, e.g., per a geological formation and per well. Thus, if a well transcends two or more geological formations, a summarized numerical index can be obtained for each one of the formations. Then for each well and for each formation, all the observations can be gathered and then three or more summarized derived properties can be extracted. These extracted data can include, for any formation or well: the maximum hydrocarbon show index, the minimum, the average, the standard deviation, and other parameters which can sufficiently characterize the data in an array.

Accordingly, and merely by way of illustrative example in accordance with one or more embodiments, FIG. 6 depicts a transformation of data from a larger database of hydrocarbon show indices to a summarized database as noted above. In principle, this may be regarded (illustratively and non-restrictively) as transforming data from a first database into data for a second database via the aforementioned second protocol. Accordingly, indicated at 654 is a database (or “first database” or “raw database”) including data transformed from the classified/characterized raw data 353 shown in FIG. 3. Here, with respect to a single well (Well 1) the data include depth, formation and a numerical hydrocarbon show index (“HC Index”) on the scale of 0 to 1 discussed herein. This database 654 then serves as input for transformation into a summarized database (or “second database”) as indicated at 655. The summarized database 655 then provides summarized values for each formation (A and B) in Well 1, including a maximum show index, an average show index, a minimum show index and the number of observations taken in each case. The summarized (or second) database 655 may also be termed or regarded as a “processed database”.

In accordance with one or more embodiments, the summarized database 655 is then provided for mapping of geological properties via one or more interpolation methods (see FIG. 2, 257), using the input maps described above (see FIG. 2, 251). Any of a great variety of methods can be utilized for the purpose, wherein scattered data can be mapped via utilizing one or more methods including (but not limited to) kriging, simple gridding, or linear, quadratic, spline, cubic, and other interpolation methods. Existing geological maps may be utilized for this purpose, at least to create a two-dimensional rendition. As an alternative, input index values may be georeferenced and are associated with given depths, such that hydrocarbon show maps may be rendered or represented as three-dimensional. In that case, interpolations methods can involve cross-referencing index values with existing geological maps, and creating new three-dimensional hydrocarbon show maps.

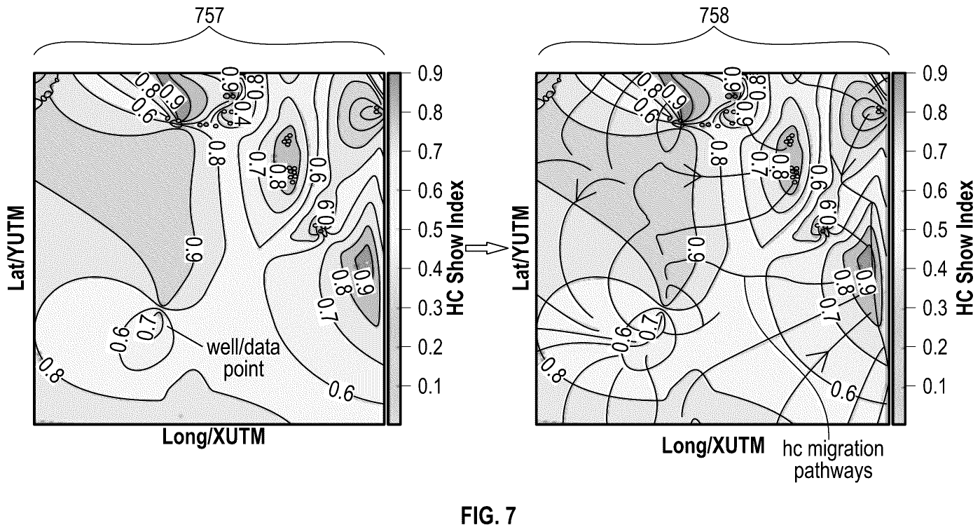

Returning to FIG. 2, in accordance with one or more embodiments, as an additional step, hydrocarbon show-based migration pathways can be derived from the interpolated summarized attributes and analyzed 258. In yet an additional step (259), the migration pathways and maps can be compared with other methods that create hydrocarbon pathways and help with quality control in basin modeling and hydrocarbon generation, and in migration modeling in a basin. Thus merely for illustrative purposes, FIG. 7 illustrates a working example of maps that can be derived on the basis of summarized index data.

Accordingly, in accordance with one or more embodiments and as shown in FIG. 7, a first map 757 can be developed to show summarized hydrocarbon show indices (such as the data from 655 in FIG. 6), mapped onto input geological property maps (see FIG. 2, 251). This can then be transformed into a second map 758, where migration pathways are determined and visually overlaid. Particularly, gradients determined from the first map 757 can be employed to map migration pathways in the second map 758. Then, the migration pathways from second map 758 can be compared with other methods for determining hydrocarbon migration pathways, and thereby help provide even more accurate modeling of hydrocarbon generation and migration modeling in a basin (see FIG. 2, 259). Related results can then be used to risk geological prospects for the chance of hydrocarbon presence and the charge history of a specific area.

Generally, by way of advantages in accordance with one or more embodiments, hydrocarbon show data accumulated over time can deduce important geological information about the geographic distribution of oil and gas prospects in the subsurface. The spatial mapping of hydrocarbon show data can highlight potential zones for future oil and gas exploration prospects. In the geological modeling of petroleum migration, hydrocarbon show data can be used for quality checks and to constrain petroleum migration in the subsurface. Accordingly, the use of numerical indices to characterize hydrocarbon show observations, as broadly contemplated herein, can provide an even more efficient and effective medium for availing valuable insights, information and data to the full benefit of the tasks just mentioned.

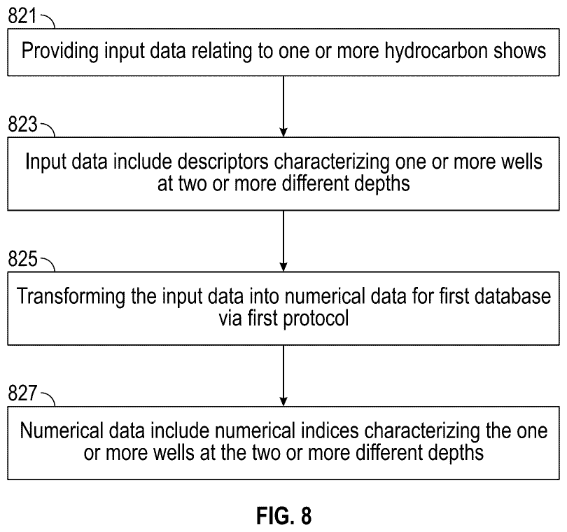

FIG. 8 shows a flowchart of a method, as a general overview of steps which may be carried out in accordance with one or more embodiments described or contemplated herein. Specifically, FIG. 8 describes a method of objectively classifying hydrocarbon shows. One or more blocks in FIG. 8 may be performed using one or more components as described in FIGS. 1-7 and 9. While the various blocks in FIG. 8 are presented and described sequentially, one of ordinary skill in the art will appreciate that some or all of the blocks may be executed in different orders, may be combined or omitted, and some or all of the blocks may be executed in parallel. Furthermore, the blocks may be performed actively or passively.

As such, in accordance with one or more embodiments, using a computer processor, input data relating to one or more hydrocarbon shows are provided (821). By way of illustrative example, this may correspond to provision of unstructured hydrocarbon show descriptions and their classification and characterization, as indicated at 252 and 253 in FIG. 2. The input data include descriptors characterizing one or more wells at two or more different depths (823). By way of illustrative example, such input data may appear in the manner of the classified and characterized raw data indicated at 353 in FIG. 3. Using the computer processor, the input data are transformed into numerical data for a first database via a first protocol (825). By way of illustrative example, this may correspond to the transformation of classified/characterized raw data to hydrocarbon show indices as indicated at 253, 254 and 256 in FIG. 2. The numerical data include numerical indices characterizing the one or more wells at the two or more different depths (827). By way of illustrative example, such numerical data may appear in the manner of the database indicated at 654 in FIG. 6.

FIG. 9 schematically illustrates a computing device and related components, in accordance with one or more embodiments. As such, FIG. 9 generally depicts a block diagram of a computer system 932 used to provide computational functionalities associated with described algorithms, methods, functions, processes, flows, and procedures as described in this disclosure, according to one or more embodiments. In this respect, computer 932 may be utilized in communication with an arrangement or venue for analyzing rock samples, such as that (140) described and illustrated with respect to FIG. 1, either locally or remotely via an internal or external network 944.

In accordance with one or more embodiments, the illustrated computer 932 is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer 932 may include a computer that includes an input device, such as a keypad, keyboard, touch screen, or other device that can accept user information, and an output device that conveys information associated with the operation of the computer 932, including digital data, visual, or audio information (or a combination of information), or a GUI.

The computer 932 can serve in a role as a client, network component, a server, a database or other persistency, or any other component (or a combination of roles) of a computer system for performing the subject matter described in the instant disclosure. The illustrated computer 932 is communicably coupled with a network 944. In some implementations, one or more components of the computer 932 may be configured to operate within environments, including cloud-computing-based, local, global, or other environment (or a combination of environments).

At a high level, the computer 932 is an electronic computing device operable to receive, transmit, process, store, or manage data and information associated with the described subject matter. According to some implementations, the computer 932 may also include or be communicably coupled with an application server, e-mail server, web server, caching server, streaming data server, business intelligence (BI) server, or other server (or a combination of servers).

The computer 932 can receive requests over network 944 from a client application (for example, executing on another computer 932) and responding to the received requests by processing the said requests in an appropriate software application. In addition, requests may also be sent to the computer 932 from internal users (for example, from a command console or by other appropriate access method), external or third-parties, other automated applications, as well as any other appropriate entities, individuals, systems, or computers.

Each of the components of the computer 932 can communicate using a system bus 933. In some implementations, any or all of the components of the computer 932, both hardware or software (or a combination of hardware and software), may interface with each other or the interface 934 (or a combination of both) over the system bus 933 using an application programming interface (API) 942 or a service layer 943 (or a combination of the API 942 and service layer 943. The API 942 may include specifications for routines, data structures, and object classes. The API 942 may be either computer-language independent or dependent and refer to a complete interface, a single function, or even a set of APIs. The service layer 943 provides software services to the computer 932 or other components (whether or not illustrated) that are communicably coupled to the computer 932. The functionality of the computer 932 may be accessible for all service consumers using this service layer. Software services, such as those provided by the service layer 943, provide reusable, defined business functionalities through a defined interface. For example, the interface may be software written in JAVA, C++, or other suitable language providing data in extensible markup language (XML) format or another suitable format. While illustrated as an integrated component of the computer 932, alternative implementations may illustrate the API 942 or the service layer 943 as stand-alone components in relation to other components of the computer 932 or other components (whether or not illustrated) that are communicably coupled to the computer 932. Moreover, any or all parts of the API 942 or the service layer 943 may be implemented as child or sub-modules of another software module, enterprise application, or hardware module without departing from the scope of this disclosure.

The computer 932 includes an interface 934. Although illustrated as a single interface 934 in FIG. 9, two or more interfaces 934 may be used according to particular needs, desires, or particular implementations of the computer 932. The interface 934 is used by the computer 932 for communicating with other systems in a distributed environment that are connected to the network 944. Generally, the interface 934 includes logic encoded in software or hardware (or a combination of software and hardware) and operable to communicate with the network 944. More specifically, the interface 934 may include software supporting one or more communication protocols associated with communications such that the network 944 or interface's hardware is operable to communicate physical signals within and outside of the illustrated computer 932.

The computer 932 includes at least one computer processor 935. Although illustrated as a single computer processor 935 in FIG. 9, two or more processors may be used according to particular needs, desires, or particular implementations of the computer 932. Generally, the computer processor 935 executes instructions and manipulates data to perform the operations of the computer 932 and any algorithms, methods, functions, processes, flows, and procedures as described in the instant disclosure, such as the data transformation processes (256) described with respect to FIG. 2 and elsewhere herein.

The computer 932 also includes a memory 936 that holds data for the computer 932 or other components (or a combination of both) that can be connected to the network 944. For example, memory 936 can be a database storing data consistent with this disclosure. Although illustrated as a single memory 936 in FIG. 9, two or more memories may be used according to particular needs, desires, or particular implementations of the computer 932 and the described functionality. While memory 936 is illustrated as an integral component of the computer 932, in alternative implementations, memory 936 can be external to the computer 932.

The application 937 is an algorithmic software engine providing functionality according to particular needs, desires, or particular implementations of the computer 932, particularly with respect to functionality described in this disclosure. For example, application 937 can serve as one or more components, modules, applications, etc. Further, although illustrated as a single application 937, the application 937 may be implemented as multiple applications 937 on the computer 932. In addition, although illustrated as integral to the computer 932, in alternative implementations, the application 937 can be external to the computer 932.

There may be any number of computers 932 associated with, or external to, a computer system containing computer 932, wherein each computer 932 communicates over network 944. Further, the term “client,” “user,” and other appropriate terminology may be used interchangeably as appropriate without departing from the scope of this disclosure. Moreover, this disclosure contemplates that many users may use one computer 932, or that one user may use multiple computers 932.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method, comprising:
providing, using a computer processor, input data relating to one or more hydrocarbon shows;
wherein the input data include descriptors characterizing one or more wells at two or more different depths; and
transforming, using the computer processor, the input data into numerical data for a first database via a first protocol;
wherein the numerical data include numerical indices characterizing the one or more wells at the two or more different depths.

2. The method according to claim 1, wherein:
the descriptors include one or more text descriptors; and
transforming via the first protocol comprises converting the text descriptors into the numerical data for the first database,
wherein the numerical indices objectively grade the one or more hydrocarbon shows at the two or more different depths.

3. The method according to claim 1, wherein the descriptors correspond to samples taken from the one or more wells at the two or more different depths.

4. The method according to claim 3, wherein the numerical indices are based on one or more of:
rock stain type, hydrocarbon show type, cut type, cut degree, rock stain degree, rock fluorescence degree and odor.

5. The method according to claim 1, wherein the numerical indices each indicate a strong, moderate or weak hydrocarbon show category wherein:
the strong category represents direct evidence of producible hydrocarbons;
the moderate category represents direct evidence of hydrocarbons that cannot be produced; and
the weak category represents indirect evidence for a presence of hydrocarbons but is inconclusive.

6. The method according to claim 1, further comprising:
transforming, using the computer processor, the data from the first database into data for a second database via a second protocol;
wherein the second database includes summarized data for each of one or more formations in each of the one or more wells, wherein each of the one or more formations correspond to one or more depths.

7. The method according to claim 6, wherein the summarized data include one or more of an average, a minimum and a maximum of numerical indices from one or more depths corresponding to a formation.

8. The method according to claim 6, further comprising:
providing, using the computer processor, one or more input maps; and
appending, using the computer processor, the summarized data to the one or more input maps to create a first output map.

9. The method according to claim 8, further comprising:
determining, using the computer processor, one or more hydrocarbon migration pathways based on the summarized data and the first output map; and
creating, using the computer processor, a second output map which shows the one or more hydrocarbon migration pathways.

10. A system for objectively classifying hydrocarbon shows, comprising:
a sample collector that collects one or more rock samples from a wellbore, each of the one or more rock samples corresponding to one or more hydrocarbon shows;
an arrangement for analyzing the rock samples; and
a computer processor operatively connected to the sample collector and arrangement and comprising functionality for:
providing input data relating to the one or more hydrocarbon shows, wherein the input data correspond to analyzed rock samples;
wherein the input data include descriptors characterizing one or more wells at two or more different depths; and
transforming the input data into numerical data for a first database via a first protocol;
wherein the numerical data include numerical indices characterizing the one or more wells at the two or more different depths.

11. The system according to claim 10, wherein:
the descriptors include one or more text descriptors; and
transforming via the first protocol comprises converting the text descriptors into the numerical data for the first database,
wherein the numerical indices objectively grade the one or more hydrocarbon shows at the two or more different depths.

12. The system according to claim 10, wherein the descriptors correspond to samples taken from the one or more wells at the two or more different depths.

13. The system according to claim 12, wherein the numerical indices are based on one or more of: rock stain type, hydrocarbon show type, cut type, cut degree, rock stain degree, rock fluorescence degree and odor.

14. The system according to claim 10, wherein the numerical indices each indicate a strong, moderate or weak hydrocarbon show category wherein:
the strong category represents direct evidence of producible hydrocarbons;
the moderate category represents direct evidence of hydrocarbons that cannot be produced; and
the weak category represents indirect evidence for a presence of hydrocarbons but is inconclusive.

15. The system according to claim 10, the computer processor further comprising functionality for:
transforming the data from the first database into data for a second database via a second protocol;
wherein the second database includes summarized data for each of one or more formations in each of the one or more wells, wherein each of the one or more formations correspond to one or more depths.

16. The system according to claim 15, wherein the summarized data include one or more of an average, a minimum and a maximum of numerical indices from one or more depths corresponding to a formation.

17. The system according to claim 15, the computer processor further comprising functionality for:
providing one or more input maps; and
appending the summarized data to the one or more input maps to create a first output map.

18. The system according to claim 17, the computer processor further comprising functionality for:
determining one or more hydrocarbon migration pathways based on the summarized data and the first output map; and
creating a second output map which shows the one or more hydrocarbon migration pathways.

19. A non-transitory computer readable medium storing instructions executable by a computer processor, the instructions comprising functionality for:
providing input data relating to one or more hydrocarbon shows;
wherein the input data include descriptors characterizing one or more wells at two or more different depths; and
transforming the input data into numerical data for a first database via a first protocol;
wherein the numerical data include numerical indices characterizing the one or more wells at the two or more different depths.

20. The non-transitory computer readable medium according to claim 19, wherein:
the descriptors include one or more text descriptors; and
transforming via the first protocol comprises converting the text descriptors into the numerical data for the first database,
wherein the numerical indices objectively grade the one or more hydrocarbon shows at the two or more different depths.
